(19) United States
(12) Patent Application Publication
(10) Pub. No.: US 2015/0034102 A1
(43) Pub. Date: Feb. 5, 2015

(54) Solar Powered Electric Cigarette

(71) Applicant: Farhad Faramarzian, Marina Del Rey, CA (US)

(72) Inventor: Farhad Faramarzian, Marina Del Rey, CA (US)

(21) Appl. No.: 14/328,420

(22) Filed: Jul. 10, 2014

Related U.S. Application Data
(60) Provisional application No. 61/845,311, filed on Jul. 11, 2013.

(51) Int. Cl. A24F 47/00; H01L 31/042

(52) U.S. Cl. CPC A24F 47/008; H01L 31/042
USPC 131/328; 131/329

(57) ABSTRACT

An electric cigarette (EC) is disclosed having an array of solar cells that are mounted directly on an outer surface of the EC. The solar cells are provided to recharge an internal battery for the EC. In more detail, the EC includes a base member for holding a rechargeable battery, a tank section for holding and selectively vaporizing a liquid, and a mouthpiece. For example, the liquid can contain nicotine and/or a flavoring. A heating element is submerged in the liquid. For the electric cigarette, a user depressible switch is mounted on the base member to selectively connect the rechargeable battery with the heating element to heat the liquid. A vaporizer is provided to vaporize the heated liquid and output a vapor. The vapor flows through a passageway in the EC from the vaporizer to the mouthpiece and exits the EC though a hole in the mouthpiece.

This application claims the benefit of U.S. Provisional Patent Application Ser. No. 61/845,311, filed Jul. 11, 2013. The entire contents of Application Ser. No. 61/845,311 are hereby incorporated by reference herein.

### FIELD OF THE INVENTION

The present invention pertains generally to electric cigarettes. More particularly, the present invention pertains to electric cigarettes that have an internal battery for vaporizing a liquid to generate an air/vapor mixture that can be inhaled by a user. The present invention is particularly, but not exclusively, useful as an electric cigarette which uses solar energy to charge an internal battery.

### BACKGROUND OF THE INVENTION

Electric cigarettes (EC), sometimes referred to as ‘electronic cigarettes’, employ a battery operated vaporizer to simulate a smoking experience. The inhalable vapor produced by the ECs can include nicotine, flavorings, or both.

In terms of construction, a typical EC includes a battery, a vaporizer and a tank of vaporizable liquid. During use, the tank of vaporizable liquid empties and the battery dies down. For some arrangements, one or more of the EC components are designed to be replaced by the user. For example, an empty tank can be replaced with a full tank of vaporizable liquid.

In some instances, a used battery can be replaced with a fresh battery. However, replacing a dead battery can result in several adverse consequences. First, disposal of batteries can cause environmental issues and require special handling considerations due to the presence of hazardous chemicals inside the battery. In addition, constantly changing out batteries can be expensive. Lastly, battery replacement is oftentimes inconvenient. In this regard, replacement EC batteries are generally non-standard in nature, and are generally only available from specialty retailers. Moreover, should an EC battery die under circumstances in which a replacement battery is not readily available, the conventional EC is rendered substantially useless.

In light of the above it is an object of the present invention to provide an electric cigarette having a rechargeable battery and a means for converting ordinary sunlight into electrical energy to charge the battery. Another object of the present invention is to provide an electric cigarette having a useful life that is longer than the life provided by a single battery. Still another object of the present invention is to provide a solar powered electric cigarette that is easy to use and comparatively cost effective.

### SUMMARY OF THE INVENTION

An electric cigarette (EC) in accordance with the present invention includes an array of solar cells as its means for generating electrical energy. In particular, the array of solar cells (alternatively, a set of sub-arrays of solar cells) is mounted directly on an outer surface of the EC. The purpose here is to position the array for exposure to light energy that will be collected and converted to electrical energy. As envisioned for the present invention, a normal exposure of the EC to light energy during everyday use will be sufficient to maintain an operational charge for the EC.

Structurally, the EC includes three interconnecting segments. These are: 1) a base member for holding a rechargeable battery; 2) a tank section for holding and selectively vaporizing a liquid; and 3) a mouthpiece (inhaler). In combination, the tank section is positioned between the base member and the mouthpiece, and it is connected with them to establish an elongated EC.

It is an important aspect of the present invention that an array of solar cells, or a set of sub-arrays, is mounted onto the outer surface of the base member. The solar cells used in the array (or sub-arrays) may be of any type well known in the pertinent art. In the event, the array must be suitable for being mounted on the base member. For this purpose, the solar cells may either be directly conformable to the outer surface of the base member, or they may be the more conventional flat solar cells. In the latter case, flat solar cells can be arranged on the base member with their surfaces oriented substantially parallel to the longitudinal axis of the EC. When so arranged, it will happen that an intersection angle, φ, is created between radially adjacent cells. Geometrically, this intersection angle, φ, will necessarily be greater than zero, but it can be varied, as desired, to be less than or greater than ninety degrees (90°>φ<90°).

Depending on functional and/or aesthetic interests for the EC, the array (set of sub-arrays) of solar cells may be presented in any of several configurations. For one, an array of solar cells may be presented as a continuous surface that extends longitudinally between a proximal end and a distal end of the base member of the EC. In alternate configurations, a plurality of sub-arrays can be presented. Specifically, each sub-array in a set can be configured either as elongated sections that are longitudinally oriented on the base member, or they can be annular shaped and radially oriented on the base member.

In an operation of the EC, a user will depress a switch that is mounted on the base member to activate the EC. This activation then connects the rechargeable battery with a heating element which is submerged in the liquid that is being held in the tank section of the EC. This connection heats the liquid. The heated liquid is then vaporized by a vaporizer in the tank section that is also activated by electrical energy from the rechargeable battery. Also, as the switch is being depressed, the user draws an air/vapor mixture into the mouthpiece, through an air passageway for inhalation. Upon completion of the inhalation, the switch is released. As noted above, electrical energy for this operation is generated by the array of solar cells.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1 is a perspective view of the electric cigarette of the present invention;

FIG. 2 is a cross-section view of the electric cigarette of the present invention as seen along the line 2-2 in FIG. 1;

FIG. 3A is a cross-section view of the electric cigarette of the present invention as seen along the line 3-3 in FIG. 1 wherein the solar cell array is conformable to the outer surface of the base member of the electric cigarette;

FIG. 3B is a cross-section view as in FIG. 3A wherein the solar cell array is characterized by an intersection angle, φ, less than ninety degrees (φ<90°) between adjacent solar cells;

FIG. 3C is a cross-section view as in FIG. 3A wherein the solar cell array is characterized by an intersection angle, φ, greater than ninety degrees (φ>90°) between adjacent solar cells;

FIG. 4A is an alternate embodiment of the electric cigarette of the present invention including a plurality of elongated sub-arrays; and

FIG. 4B is an alternate embodiment of the electric cigarette of the present invention including a plurality of annular sub-arrays.

### DESCRIPTION OF THE PREFERRED EMBODIMENTS

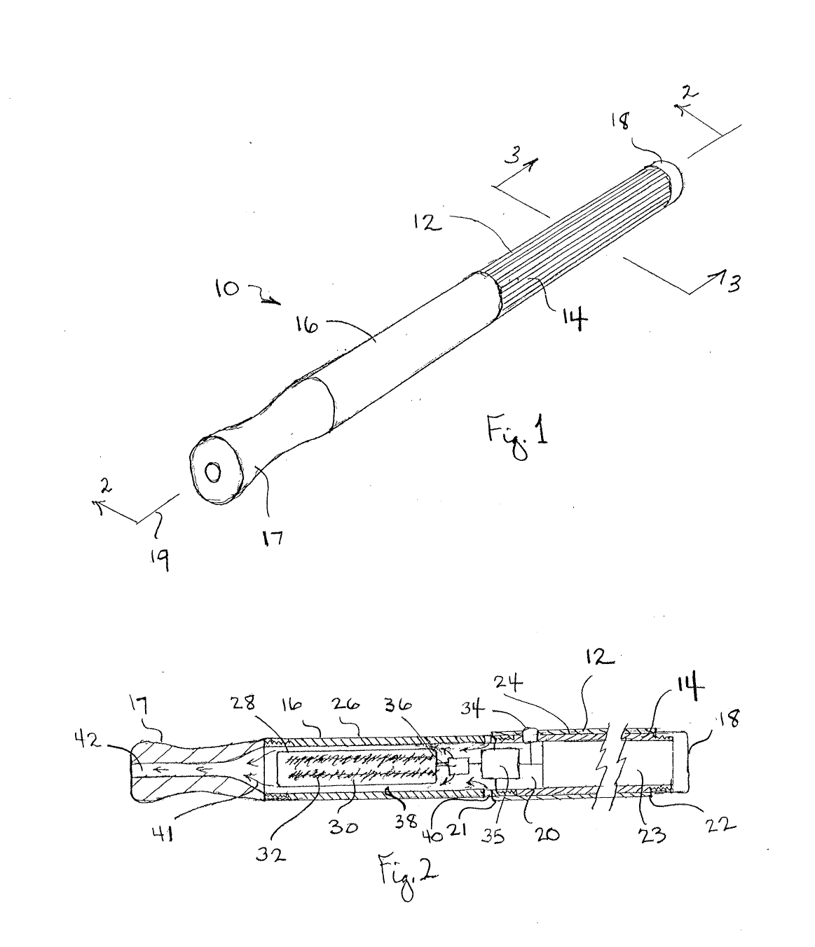

With initial reference to FIG. 1, an electric cigarette (EC) in accordance with the present invention is shown and generally designated 10. As shown, the EC 10 can include solar cells 12. The solar cells 12 can be an array of solar cells 12 as shown in FIG. 1 or a set of sub-arrays of solar cells as described below. In either case, the solar cells 12 generate electrical energy when exposed to incident light, such as ordinary sunlight. As envisioned for the present invention, the solar cells 12 will be selected having a capacity such that a normal exposure of the EC 10 to light energy during everyday use will be sufficient to maintain an operational charge for the EC 10.

Continuing with FIG. 1, it can be seen that the EC 10 includes a base member 14, a tank section 16, a mouthpiece 17 and a cap 18. As shown, the tank section 16 is positioned between the base member 14 and the mouthpiece 17, and is connected with them to establish an elongated EC 10 having a longitudinal axis 19.

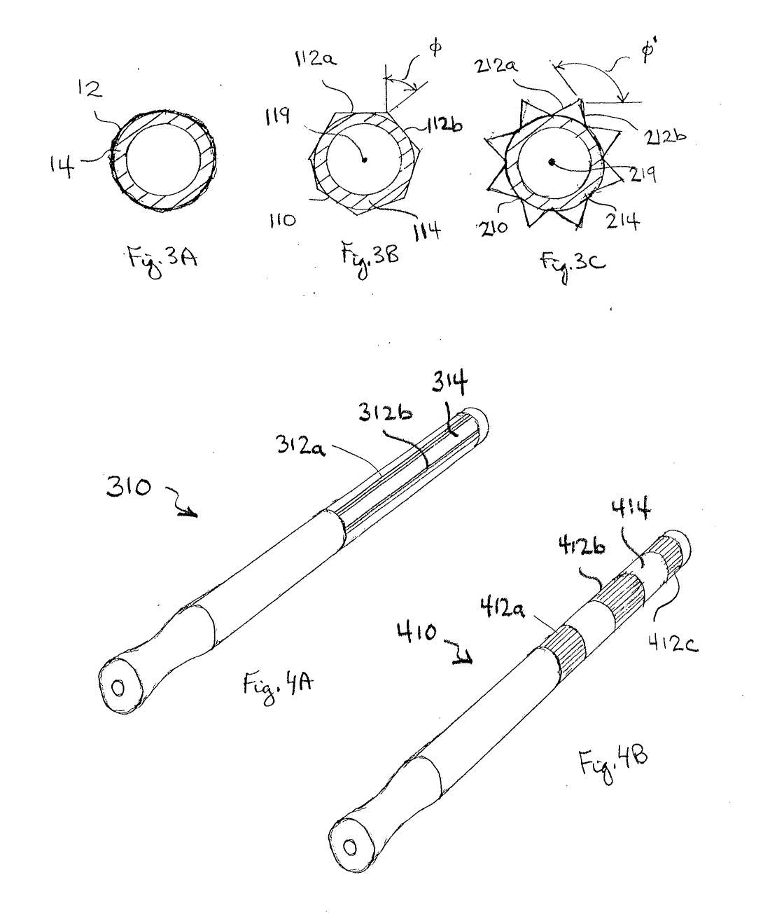

The details of the EC 10 components can best be appreciated with cross-reference to FIGS. 1 and 2. As shown there, the base member 14 can be tubular, e.g. shaped as a hollow cylinder, surround a chamber 20 and extend from a proximal end 21 to a distal end 22. Also shown, a rechargeable storage battery 23 (or other storage device such as a capacitor) can be fitted in the chamber 20 and affixed to the cylindrical base member 14. FIGS. 2 and 3A also show that the array of solar cells 12 can be mounted directly on an outer surface 24 of the base member 14. For this embodiment, the array of solar cells 12 is conformable to the outer surface 24 of the base member 14.

It can further be seen from FIG. 2 that the tank section 16 includes an outer hollow cylinder 26 which houses a tank 28 (i.e. liquid compartment) that holds a vaporizable liquid 30. For example, the liquid 30 can contain nicotine and/or a flavoring. A heating element 32 is submerged in the liquid 30, as shown. FIG. 2 also shows that a user depressible switch 34 is mounted on the base member 14 to selectively activate the EC 10 by connecting the rechargeable battery 23 with the heating element 32. A control circuit 35 having an integral voltage regulator can be connected to the switch 34 to control the voltage on the heating element 32 within a pre-determined voltage range and/or control the charging voltage for current flowing from the solar cells 12 to the battery 23.

FIG. 2 also shows that a vaporizer 36 is disposed in the tank section 16 and connected to receive heated liquid 30 from the tank 28. For the EC 10, the vaporizer 36 is configured to vaporize the heated liquid 30 and output a vapor. As FIG. 2 shows, a passageway 38 is provided between the tank 28 and cylinder 26 to allow the vapor produced at the vaporizer 36 to reach the mouthpiece 17. It can further be seen that a vent 40 is formed in cylinder 26 to allow air to be introduced into the passageway 38. Also, mouthpiece 17 is formed with a through-hole 42 that is in fluid communication with the passageway 38. With this arrangement, air from the vent 40 and the vapor generated at the vaporizer 36 are allowed to pass through the mouthpiece 17 (see arrow 41) and reach the user (user not shown).

FIG. 3B shows another embodiment of an EC 110 in which a plurality of conventional flat solar cells 112a, 112b can be arranged on the base member 114 with their surfaces oriented substantially parallel to the longitudinal axis 119 of the EC 110. As shown, with this arrangement, an intersection angle, φ, is created between radially adjacent solar cells 112a, 112b. For the arrangement shown in FIG. 3B, the intersection angle, φ, is less than ninety degrees (90°).

FIG. 3C shows another embodiment of an EC 210 in which a plurality of conventional flat solar cells 212a, 212b can be arranged on the base member 214 with their surfaces oriented substantially parallel to the longitudinal axis 219 of the EC 210. As shown, with this arrangement, an intersection angle, φ′, is created between radially adjacent cells 212a, 212b. For the arrangement shown in FIG. 3C, the intersection angle, φ′, is greater than ninety degrees (90°).

FIG. 4A shows an alternate embodiment of an electric cigarette that is generally designated 310. As shown, EC 310 includes a plurality of elongated solar cell sub-arrays 312a, 312b that are spaced apart around the circumference of the base member 314.

FIG. 4B shows another alternate embodiment of an electric cigarette that is generally designated 410. As shown, EC 410 includes a plurality of annular solar cell sub-arrays 412a, 412b, 412c that are spaced apart along the length of the base member 414.

While the particular Solar Powered Electric Cigarette as herein shown and disclosed in detail is fully capable of obtaining the objects and providing the advantages herein before stated, it is to be understood that it is merely illustrative of the presently preferred embodiments of the invention and that no, limitations are intended to the details of construction or design herein shown other than as described in the appended claims.

What is claimed is:

1. A solar powered electric cigarette which comprises:
an elongated substantially tubular shaped base member having a proximal end and a distal end with a chamber extending therebetween, wherein the base member has an outer surface surrounding the chamber;
a plurality of solar cells mounted on the outer surface of the base member to form an array for use in generating electrical energy;
a storage battery positioned in the chamber and connected to the array for receiving and storing electrical energy as it is generated by the solar cells;
a tank section formed with a liquid compartment for holding a liquid and an air passage passing through the tank section and bypassing the liquid compartment;
a heating element inside the liquid compartment for submersion in the liquid; and
a switch for selectively interconnecting the storage battery with the heating element when the tank section is joined to the proximal end of the base member, and wherein the switch is operated by a user to heat the liquid in the liquid compartment and create a vapor from the liquid, for mixing the vapor with air from the passageway during an inhalation of the vapor/air mixture by the user.

2. An electric cigarette as recited in claim 1 further comprising a mouthpiece connected with the tank section opposite the base member for use by the user during an inhalation.

3. An electric cigarette as recited in claim 1 wherein the array of solar cells extends around the base member and extends between the proximal end and the distal end.

4. An electric cigarette as recited in claim 1 wherein the array of solar cells comprises a plurality of sub-arrays, and wherein each sub-array is individually oriented on the outer surface of the base member.

5. An electric cigarette as recited in claim 1 wherein each solar cell has a substantially flat surface for collecting light, wherein the base member defines a longitudinal axis, and wherein the flat surface of each solar cell is substantially parallel to the axis of the base member.

6. An electric cigarette as recited in claim 5 wherein an intersection angle, φ, is established between a normal to the flat surface of a solar cell and a normal to the flat surface of at least one adjacent solar cell, and wherein the angle, φ, is greater than zero degrees (φ>90°).

7. An electric cigarette as recited in claim 6 wherein the intersection angle, φ, is less than ninety degrees (φ<90°).

8. An electric cigarette as recited in claim 1 wherein the liquid contains nicotine and a flavoring.

9. An electric cigarette as recited in claim 1 wherein each solar cell is conformable with the outer surface of the base member.

10. A solar powered electric cigarette which comprises:
an elongated substantially tubular shaped base member having a proximal end and a distal end with a chamber extending therebetween, wherein the base member has an outer surface surrounding the chamber;
a plurality of solar cells mounted on the outer surface of the base member to form an array for use in generating electrical energy;
a storage means positioned in the chamber and connected to the array for receiving and storing electrical energy as it is generated by the solar cells;
a means for holding a liquid, wherein the holding means is formed with a liquid compartment and an air passage bypassing the liquid compartment;
a means for heating the liquid; and
a switch for selectively interconnecting the storage means with the heating means when the holding means is joined to the proximal end of the base member, and wherein the switch is operated by a user to heat the liquid in the liquid compartment and create a vapor from the liquid, for mixing the vapor with air from the passageway during an inhalation of the vapor/air mixture by the user.

11. An electric cigarette as recited in claim 10 further comprising a mouthpiece.

12. An electric cigarette as recited in claim 10 wherein the array of solar cells extends around the base member and extends between the proximal end and the distal end.

13. An electric cigarette as recited in claim 10 wherein the array of solar cells comprises a plurality of sub-arrays, and wherein each sub-array is individually oriented on the outer surface of the base member.

14. An electric cigarette as recited in claim 10 wherein each solar cell has a substantially flat surface for collecting light, wherein the base member defines a longitudinal axis, and wherein the flat surface of each solar cell is substantially parallel to the axis of the base member.

15. An electric cigarette as recited in claim 14 wherein an intersection angle, φ, is established between a normal to the flat surface of a solar cell and a normal to the flat surface of at least one adjacent solar cell, and wherein the angle, φ, is greater than zero degrees (φ>0°).

16. An electric cigarette as recited in claim 15 wherein the intersection angle, φ, is less than ninety degrees (φ<90°).

17. An electric cigarette as recited in claim 10 wherein the liquid contains nicotine and a flavoring.

18. An electric cigarette as recited in claim 10 wherein each solar cell is conformable with the outer surface of the base member.

19. A method for manufacturing a solar powered electric cigarette which comprises the steps of:
providing an elongated substantially tubular shaped base member having a proximal end and a distal end with a chamber extending therebetween, wherein the base member has an outer surface surrounding the chamber;
mounting a plurality of solar cells on the outer surface of the base member to form an array for use in generating electrical energy;
positioning a storage battery in the chamber and connecting the battery to the array for receiving and storing electrical energy as it is generated by the solar cells;
establishing a tank section formed with a liquid compartment for holding a liquid and an air passage passing through the tank section and bypassing the liquid compartment;
submersing a heating element in the liquid; and
connecting a switch between the storage battery and the heating element when the tank section is joined to the proximal end of the base member, and wherein the switch is operated by a user to heat the liquid in the liquid compartment and create a vapor from the liquid, for mixing the vapor with air from the passageway during an inhalation of the vapor/air mixture by the user.

20. A method as recited in claim 19 further comprising the step of connecting a mouthpiece with the tank section opposite the base member for use by the user during an inhalation.
